(19) United States
(12) Patent Application Publication
(10) Pub. No.: US 2021/0280624 A1
(43) Pub. Date: Sep. 9, 2021

(54) IMAGING SYSTEMS WITH IMPROVED MICROLENSES FOR ENHANCED NEAR-INFRARED DETECTION

(71) Applicant: SEMICONDUCTOR COMPONENTS INDUSTRIES, LLC, Phoenix, AZ (US)

(72) Inventor: Victor LENCHENKOV, Sunnyvale, CA (US)

(73) Assignee: SEMICONDUCTOR COMPONENTS INDUSTRIES, LLC, Phoenix, AZ (US)

(21) Appl. No.: 16/810,971

(22) Filed: Mar. 6, 2020

(51) Int. Cl. H01L 27/146

(52) U.S. Cl. CPC H01L 27/14627; H01L 27/14649

(57) ABSTRACT

An imaging device may have an array of image sensor pixels that includes infrared pixels. The infrared pixels may be formed from a silicon layer and having an etched microlens on an upper surface of the silicon layer. The etched microlens may be formed as concentric circles, concentric squares, or other concentric shapes to improve the focusing of incident light on the photosensitive portion of the silicon layer. Additionally, there may be a plurality of silicon—silicon-oxide interfaces or silicon—silicon-nitride interfaces between the etched microlens and the silicon layer. These interfaces may increase the absorption of infrared light by the underlying silicon layer. Similar interfaces may be formed on a lower surface, either as an etched region or as an additional dielectric layer. Alternatively or additionally, the infrared pixels may include a conductive patch between the silicon layer and microlens that similarly increases the absorption of infrared light.

### BACKGROUND

This relates generally to imaging devices, and more particularly, to imaging sensors that include pixels having improved detection at infrared and near-infrared wavelengths.

Image sensors are commonly used in electronic devices such as cellular telephones, cameras, and computers to capture images. In a typical arrangement, an electronic device is provided with an array of image pixels arranged in pixel rows and pixel columns. Each image pixel in the array includes a photodiode that is coupled to a floating diffusion region via a transfer gate. Each pixel receives photons from incident light and converts the photons into electrical signals. Column circuitry is coupled to each pixel column for reading out pixel signals from the image pixels. Image sensors are sometimes designed to provide images to electronic devices using a Joint Photographic Experts Group (JPEG) format.

Image pixels commonly include microlenses that focus light incident on the array onto a photodetection region, which may be formed from a semiconductor material, such as silicon. The silicon may absorb photons of the light, which may then be converted into electrical signals. Absorption depth in silicon is a function of wavelength. Lower wavelength light (e.g. blue light) has a short absorption depth while long wavelength light (e.g. red light or near infrared light) has a long absorption depth. To detect long wavelength light, thick silicon is required. However, it is difficult to integrate thick silicon photodiodes in image sensors, especially Backside Illumination (BSI) image sensors. As a result, the image pixels may not accurately detect an amount of near-infrared or infrared light incident on the array.

It would therefore be desirable to provide imaging devices having image sensor pixels with microlenses that allow for improved detection at infrared and near-infrared wavelengths.

### BRIEF DESCRIPTION OF THE DRAWINGS

FIG. 1 is a diagram of an illustrative electronic device having an image sensor and processing circuitry for capturing images using an array of image pixels in accordance with an embodiment.

FIG. 2 is a diagram of an illustrative pixel array and associated readout circuitry for reading out image signals from the pixel array in accordance with an embodiment.

FIG. 3 is a cross-sectional side view of an illustrative image pixel having an etched silicon microlens with a convex shape in accordance with an embodiment.

FIG. 4 is a cross-sectional side view of an illustrative image pixel having an etched silicon microlens with multiple trenches in accordance with an embodiment.

FIG. 5A is a top view of an illustrative image pixel having an etched silicon microlens with multiple square-shaped trenches in accordance with an embodiment.

FIG. 5B is a top view of an illustrative image pixel having an etched silicon microlens with trenches of multiple shapes in accordance with an embodiment.

FIG. 5C is a top view of an illustrative image pixel having an etched silicon microlens with concentric circular-shaped trenches in accordance with an embodiment.

FIG. 6 is a cross-sectional side view of an illustrative image pixel having a conductive patch between a microlens and silicon layer.

### DETAILED DESCRIPTION

Embodiments of the present invention relate to image sensors, and more particularly, to image sensors having pixels with microlenses that allow for improved detection of infrared and near-infrared light. It will be recognized by one skilled in the art, that the present exemplary embodiments may be practiced without some or all of these specific details. In other instances, well known operations have not been described in detail in order to not unnecessarily obscure the present embodiments.

Imaging systems having digital camera modules are widely used in electronic devices such as digital cameras, computers, cellular telephones, and other electronic devices. A digital camera module may include one or more image sensors that gather incoming light to capture an image. Image sensors may include arrays of image pixels. The pixels in the image sensors may include photosensitive elements such as photodiodes that convert the incoming light into electric charge. Image sensors may have any number of pixels (e.g., hundreds or thousands or more). A typical image sensor may, for example, have hundreds, thousands, or millions of pixels (e.g., megapixels). Image sensors may include control circuitry such as circuitry for operating the image pixels and readout circuitry for reading out image signals corresponding to the electric charge generated by the photosensitive elements.

Image sensor pixels may be formed from semiconductor material, such as silicon, to absorb photons from light incident on the pixels and convert the photons into electrical signals. In general, image sensor pixels may detect light at any desired wavelength and may generally be overlapped by a color filter to only pass light of a certain color to the underlying pixels. While conventional image sensor pixels may have silicon photosensitive regions that are effective at absorbing light at visible wavelengths, silicon is generally not as effective at absorbing infrared and near-infrared light (e.g., light at longer wavelengths than visible light). In other words, infrared light may need to travel through silicon for more time before being absorbed. As a result, the silicon in image sensor pixels configured to detect infrared and near-infrared light may need to be made thicker (in other words have a longer path length). For example, the silicon may need to be double the thickness, three times the thickness, or four times the thickness of a conventional image pixel. However, increasing the thickness of an image sensor pixel may increase the cost of producing the image sensor pixel and may degrade optical performance as overlying layers (such as a color filter layer) may be further from the photosensitive region due to integration limitations. Therefore, it may be desired to form image pixels that absorb sufficient infrared and near-infrared light (or light at other wavelengths that are longer than visible light) by modifying the silicon substrate to form a microlens, rather than increasing its thickness.

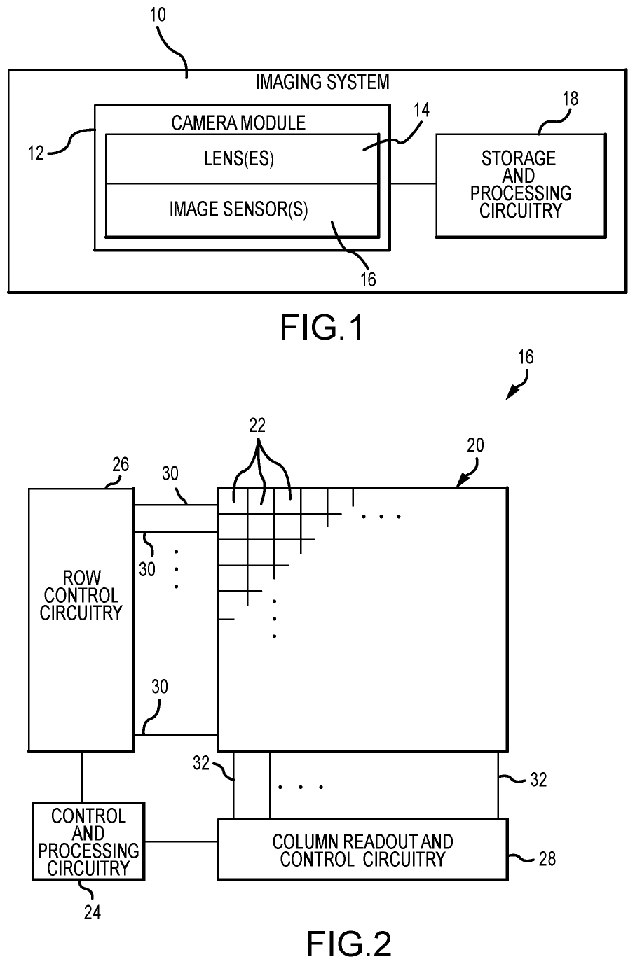

FIG. 1 is a diagram of an illustrative imaging system such as an electronic device that uses an image sensor to capture images. Electronic device 10 of FIG. 1 may be a portable electronic device such as a camera, a cellular telephone, a tablet computer, a webcam, a video camera, a video surveillance system, an automotive imaging system, a video gaming system with imaging capabilities, or any other desired imaging system or device that captures digital image data. Camera module 12 may be used to convert incoming light into digital image data. Camera module 12 may include one or more lenses 14 and one or more corresponding image sensors 16. Lenses 14 may include fixed and/or adjustable lenses and may include microlenses formed on an imaging surface of image sensor 16. During image capture operations, light from a scene may be focused onto image sensor 16 by lenses 14. Image sensor 16 may include circuitry for converting analog pixel data into corresponding digital image data to be provided to storage and processing circuitry 18. If desired, camera module 12 may be provided with an array of lenses 14 and an array of corresponding image sensors 16.

Storage and processing circuitry 18 may include one or more integrated circuits (e.g., image processing circuits, microprocessors, storage devices such as random-access memory and non-volatile memory, etc.) and may be implemented using components that are separate from camera module 12 and/or that form part of camera module 12 (e.g., circuits that form part of an integrated circuit that includes image sensors 16 or an integrated circuit within module 12 that is associated with image sensors 16). Image data that has been captured by camera module 12 may be processed and stored using processing circuitry 18 (e.g., using an image processing engine on processing circuitry 18, using an imaging mode selection engine on processing circuitry 18, etc.). Processed image data may, if desired, be provided to external equipment (e.g., a computer, external display, or other device) using wired and/or wireless communications paths coupled to processing circuitry 18.

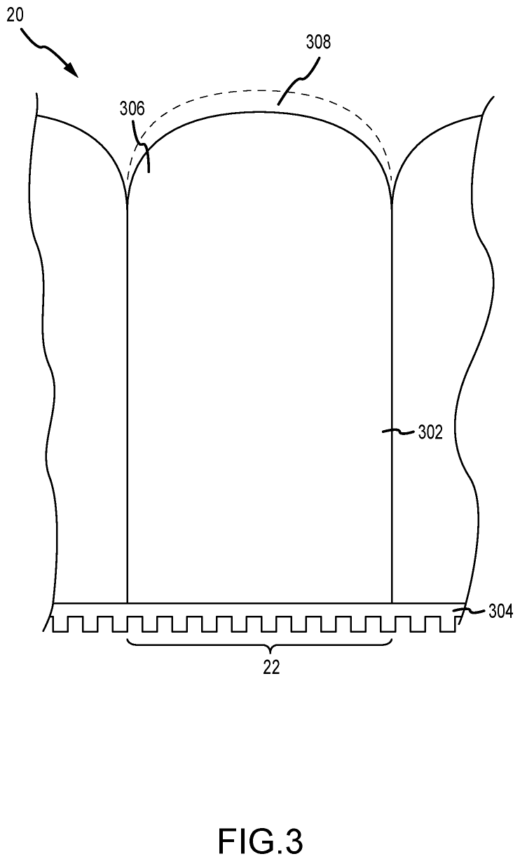

As shown in FIG. 2, image sensor 16 may include a pixel array 20 containing image sensor pixels 22 arranged in rows and columns (sometimes referred to herein as image pixels or pixels) and control and processing circuitry 24. Array 20 may contain, for example, hundreds or thousands of rows and columns of image sensor pixels 22. Control circuitry 24 may be coupled to row control circuitry 26 and image readout circuitry 28 (sometimes referred to as column control circuitry, readout circuitry, processing circuitry, or column decoder circuitry). Row control circuitry 26 may receive row addresses from control circuitry 24 and supply corresponding row control signals such as reset, row-select, charge transfer, dual conversion gain, and readout control signals to pixels 22 over row control paths 30. One or more conductive lines such as column lines 32 may be coupled to each column of pixels 22 in array 20. Column lines 32 may be used for reading out image signals from pixels 22 and for supplying bias signals (e.g., bias currents or bias voltages) to pixels 22. If desired, during pixel readout operations, a pixel row in array 20 may be selected using row control circuitry 26 and image signals generated by image pixels 22 in that pixel row can be read out along column lines 32.

Image readout circuitry 28 (sometimes referred to as column readout and control circuitry 28) may receive image signals (e.g., analog pixel values generated by pixels 22) over column lines 32. Image readout circuitry 28 may include sample-and-hold circuitry for sampling and temporarily storing image signals read out from array 20, amplifier circuitry, analog-to-digital conversion (ADC) circuitry, bias circuitry, column memory, latch circuitry for selectively enabling or disabling the column circuitry, or other circuitry that is coupled to one or more columns of pixels in array 20 for operating pixels 22 and for reading out image signals from pixels 22. ADC circuitry in readout circuitry 28 may convert analog pixel values received from array 20 into corresponding digital pixel values (sometimes referred to as digital image data or digital pixel data). Image readout circuitry 28 may supply digital pixel data to control and processing circuitry 24 and/or processor 18 (FIG. 1) over path 25 for pixels in one or more pixel columns.

If desired, image pixels 22 may include one or more photosensitive regions for generating charge in response to image light. Photosensitive regions within image pixels 22 may be arranged in rows and columns on array 20. Pixel array 20 may be provided with a color filter array having multiple color filter elements which allows a single image sensor to sample light of different colors. As an example, image sensor pixels such as the image pixels in array 20 may be provided with a color filter array which allows a single image sensor to sample red, green, and blue (RGB) light using corresponding red, green, and blue image sensor pixels arranged in a Bayer mosaic pattern. The Bayer mosaic pattern consists of a repeating unit cell of two-by-two image pixels, with two green image pixels diagonally opposite one another and adjacent to a red image pixel diagonally opposite to a blue image pixel. In another suitable example, the green pixels in a Bayer pattern are replaced by broadband image pixels having broadband color filter elements (e.g., clear color filter elements, yellow color filter elements, etc.). These examples are merely illustrative and, in general, color filter elements of any desired color and in any desired pattern may be formed over any desired number of image pixels 22.

Image sensor 16 may be configured to support a global shutter operation (e.g., pixels 22 may be operated in a global shutter mode). For example, the image pixels 22 in array 20 may each include a photodiode, floating diffusion region, and local charge storage region. With a global shutter scheme, all of the pixels in the image sensor are reset simultaneously. A charge transfer operation is then used to simultaneously transfer the charge collected in the photodiode of each image pixel to the associated charge storage region. Data from each storage region may then be read out on a per-row basis, for example.

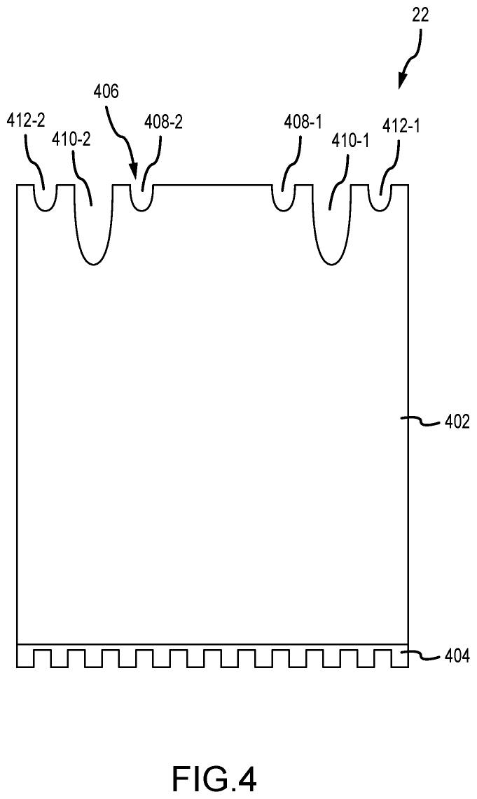

Image pixels 22 in array 20 may include structures that allow for enhanced absorption at infrared and near-infrared wavelengths (or other wavelengths that are longer than visible light wavelengths). As shown in FIG. 3, pixel 22 may be formed from silicon layer 302 and interlayer dielectric 304, which is formed on a surface of silicon layer 302. In general, silicon layer 302 may be more broadly formed from any semiconductor material. Silicon layer 302 may also be referred to as a semiconductor layer and a photosensitive region herein. To focus incident light on photosensitive layer 302, pixel 22 may include a microlens 306. Although conventional microlenses may be formed separately from silicon layer 302, it may be desirable to etch a top surface of silicon layer 302 to form microlens 306. In particular, the silicon forming layer 302 may be etched to shape the silicon into a desired shape to focus light on the photosensitive region of layer 302. For example, it may be desired to have a convex microlens 306. However, this is merely illustrative. In general, the top surface of layer 302 may be etched into any desired microlens shape, such as a concave shape or a combination shape having concave and convex portions.

Because microlens 306 may be formed from an etched surface of layer 302, it may be shaped in any desired manner to focus light as desired on the photosensitive region (e.g., as opposed to having to form individually shaped lenses prior to applying them to the surface of layer 302). For example, it may be desirable to shape microlenses at the edges of pixel array 20 with relatively larger curvatures than microlenses at the center of pixel array 20 to better redirect light incident at the edges of the array. However, this is merely illustrative. In general, microlenses 306 may be shaped the same across array 20, differently across array 20, or in any desired combination. In this way, light may be focused in a more precise manner across the array of pixels, increasing the efficiency of the image sensor.

Additionally, because silicon has a relatively high refractive index (e.g., compared to other materials that are often used to form microlenses) of approximately 3.4, silicon microlens 306 may focus higher angle light more easily on the underlying photosensitive region, thereby allowing silicon layer 302 to have a smaller height than traditional pixels. For example, the height of pixel 22 (i.e., the combined height of silicon layer 302, microlens 306, and interlayer dielectric 304) may be less than 5 microns, less than 5.5 microns, greater than 3 microns, approximately 4 microns, or any other desired height.

Etching microlens 306 from a surface of layer 302 may also increase the sensitivity of layer 302 to near-infrared or infrared light (or other light at wavelengths higher than visible light). In particular, etching the surface of layer 302 may increase the number of Si—SiO₂ interfaces through which incident light will pass (e.g., the etched silicon may have a larger surface area to which SiO₂ may be applied over the lens or which has been damaged from the etching process). This may reduce the activation energy of layer 302 below that of traditional bulk silicon. Specifically, silicon generally has an activation energy of 1.12 eV, which makes absorbing high-wavelength light difficult (e.g., high-wavelength light needs significant time within the silicon to be absorbed). However, with the increased number of Si—SiO₂ interfaces, the activation energy may be reduced to a value less than 0.8 eV, less than 0.9 eV, or to a value less than 1.0 eV, as examples. In one embodiment, layer 302 may have an activation energy of 0.7 eV after being etched to form microlens 306. Having a lower activation energy than pure silicon may allow for increased quantum efficiency at near-infrared wavelengths, infrared wavelengths, and/or other wavelengths above visible wavelengths. In other words, etching microlens 306 into a surface of silicon layer 302 may allow for increased absorption of light at wavelengths greater than visible light. In this way, etched microlens 306 may be a light-absorption-promotion structure for the pixel.

In addition to etching microlens 306 into the backside of silicon layer 302 (e.g., if the image sensor is a backside illuminated sensor), additional structures may be formed to absorb near-infrared and infrared light. For example, trenches may be formed on the frontside of silicon layer 302. As shown in FIG. 3, layer 304, which may be formed from silicon nitride, silicon oxide, or any other desired material, may be applied over silicon layer 302, and trenches may be formed within layer 304. Alternatively or additionally, the trenches may extend directly into the frontside surface of silicon layer 302. In either case, the trenches on the frontside may provide additional Si—SiO₂ interfaces (or Si—SiN) interfaces, which promote the absorption of high-wavelength light within silicon layer 302. However, these trenches are optional, and may or may not be added to a pixel having etched microlens 306.

Although the advantages of having additional Si—SiO₂ interfaces has been described, other interfaces may have desirable properties, as well. For example, it may be desirable to increase the number of Si—SiN interfaces. In general, the number of interfaces between silicon and any silicon-based compound may be increased to change the absorption properties of the pixel as desired.

Additionally, an optical stack, such as optical stack 308, may optionally be formed over silicon layer 302 and may include one or more of a color filter, a planarization layer, an antireflection layer, and any other desired optical layers. As shown in FIG. 3, these optional layers may be formed over microlens 306, if desired. In this way, microlens 306 may remain a continuous portion of silicon layer 302, which may allow for the increased absorption of high-wavelength light that was previously discussed. Alternatively or additionally, one or more layers may be formed between silicon layer 302 and silicon microlens 306. In this case, pixel 22 may not exhibit higher absorption at high wavelengths. However, silicon microlens 306 may still provide enhanced focusing ability and therefore be desirable in some circumstances. In general, the optical stack may be applied in any desired location within image pixel 22.

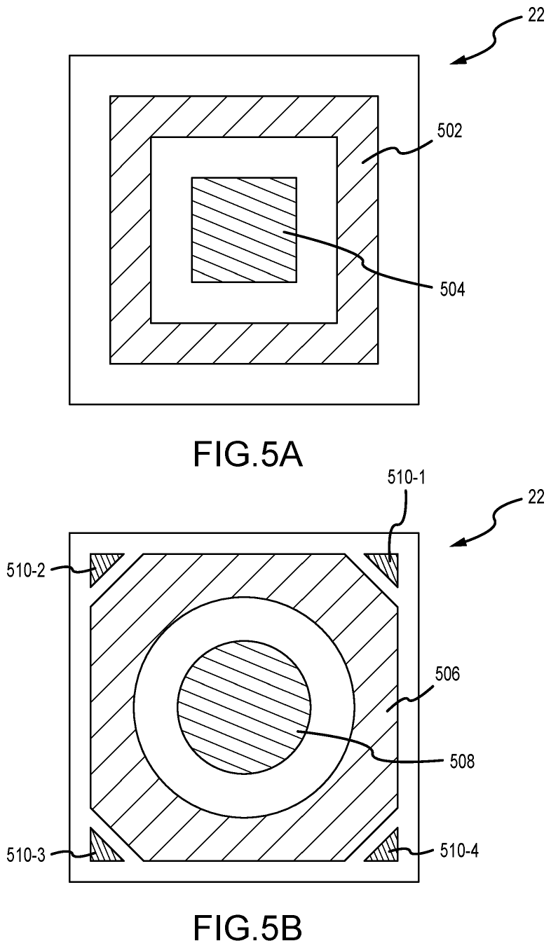

Although microlens 306 has been illustrated as a convex lens in FIG. 3, this is merely illustrative. In general, a microlens of any desired shape may be etched into the backside surface of silicon layer 304. An example of another microlens that may be used is shown in FIG. 4.

As shown in FIG. 4, microlens 406 may be etched in the backside surface of silicon layer 402. In particular, microlens 406 may be formed from trenches of varying size and depth. For example, in the example of FIG. 4, trenches 408 and 412 may be shallower than trench 410. The trenches may be formed as concentric circles in the surface of layer 402 that surround the center of the surface. However, this is merely illustrative. In general, any desired pattern may be used to etch the trenches that form microlens 406 into the frontside surface of layer 402.

Due to the presence of the multiple patterned trenches, microlens 406 may diffract light incident on pixel 22. This may allow for improved detection of high angle light, as the microlens may be patterned to diffract high-angle light that would normally be directed out of pixel 22. Maintaining the high-angle light within pixel 22 may also reduce cross-talk between adjacent pixels.

In some cases, it may be desirable to form narrower and shallower trenches at the center of pixel 22 and deeper trenches at the edges of pixel 22. This may result in a higher refractive index in the center of the pixel and a lower refractive index at the edges, due to silicon having a refractive index of approximately 3.4 and silicon oxide (which will form a portion of the etched trench) having a refractive index of approximately 1.5. In this way, the microlens may be etched to redirect light at the edges of the pixel toward the center of the photosensitive region, while allowing light at the center of the pixel to remain within the pixel, allowing for greater efficiency in some cases. However, this arrangement is merely illustrative. In some embodiments, it may be desired to have a plurality of trenches with the same width and depth, or it may be desired to have larger trenches at the edges of the pixel. In general, any desired pattern of trenches may be used.

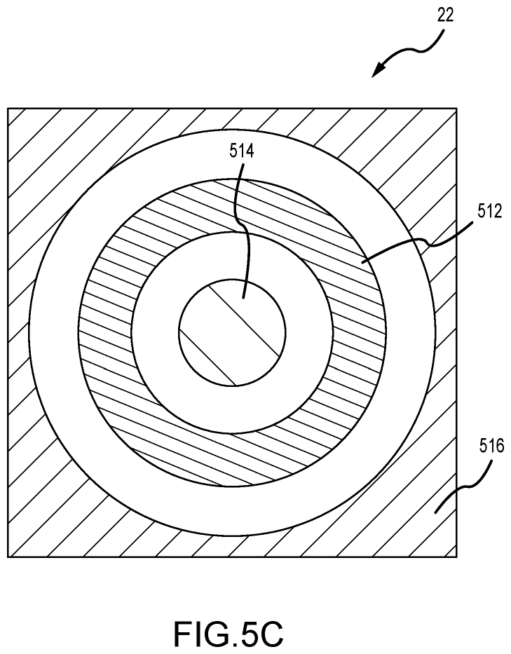

Top views of illustrative microlenses that may be etched into the backside surface of pixel 22 are shown in FIGS. 5A-C. As shown in FIG. 5A, concentric squares may be etched in the back surface of the silicon layer within pixel 22. Specifically, square 502 and central square 504 may be etched. This may diffract light incident on pixel 22 in a cross pattern of light, with a peak intensity at the center of the pixel. Although this pattern diffuses light in a specific pattern, the shape is simple to etch, and it may be satisfactory depending on the application of the corresponding image sensor.

Another illustrative etched microlens is shown in FIG. 5B. As shown in FIG. 5B, the microlens may have a first etched portion 506 and an inner circle etched portion 508. Additionally, the microlens may include corner etched portions 510. This microlens may diffract the light with fewer gaps than the concentric square pattern of FIG. 5A, which may allow the pixel to detect the light more uniformly.

A third illustrative etched microlens is shown in FIG. 5C. As shown in FIG. 5C, the microlens may have etched concentric circles 512 and 514. Additionally, the microlens may have optional etched edge portion 516. This concentric circle pattern may provide similar diffraction to the pattern described in FIG. 5A, except with the light focused in a circular pattern.

Although the three patterns in FIGS. 5A-5C have been shown, they are merely illustrative. In general, any desired pattern may be used. In some examples, the patterns in FIGS. 5A-5C may be elongated (e.g., the pattern in FIG. 5C may have elliptical-shaped etched portions rather than circular). Alternatively or additionally, the patterns may be modified to have additional etched regions. For example, the pattern of FIG. 5C may be modified to have more than two etched circular portions, more than three etched circular portions, or more than five etched circular portions, as examples. In general, the patterns shown in FIGS. 5A-C may be modified in any desired manner.

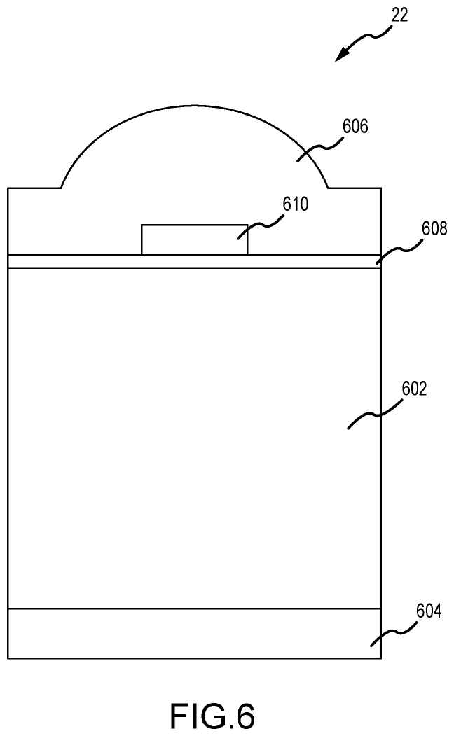

Although each of the embodiments up to this point have described increasing the focusing ability and high-wavelength absorption of pixels by etching a microlens in the backside surface of the photosensitive layer, the focusing and absorption qualities may be achieved without etching, if desired. In other words, the etched microlens may be a first type of infrared-light-absorption-promotion structure for the pixel. An example of an alternate embodiment of an infrared-light-absorption-promotion structure that maintains the focusing and absorbing abilities previously described is shown in FIG. 6.

As shown in FIG. 6, pixel 22 may include silicon layer 602, interlayer dielectric 304 on the frontside of silicon layer 602, and interfacial layer 608 on the backside of silicon layer 602. Microlens 606 may be applied over interfacial layer 608, and may be formed from acrylic, glass, polymer, or any other desired material. Rather than forming the microlens from etched silicon, as described previously, conductive patch 610 may be interposed between microlens 606 and interfacial layer 608. In particular, conductive patch 610 may be formed from tungsten, WSi, nickel, NiSi, or any other desired material, and may exhibit high infrared light absorption (e.g., may exhibit higher infrared light absorption than bulk silicon). Interfacial layer 608 may be formed from SiO₂, and may provide for an interface with the underlying silicon layer 602 that absorbs more infrared light than just silicon alone (as described previously). Coupled with conductive patch 610, which may absorb infrared light at the SiO₂—Si interface, the pixel may detect more infrared light than a traditional pixel. However, this is merely illustrative. In general, any desired materials may be used that provide increased absorbance of near-infrared or infrared light.

Although not shown in FIG. 6, pixel 22 may have a color filter layer, and any other desired optical layers, such as optional optical layers of FIG. 3. Additionally, interlayer dielectric 604 may be etched with a trench pattern, such as the pattern shown in FIGS. 3 and 4, to provide additional infrared light absorption.

Although all of the embodiments have been described with respect to their implementation in backside illuminated image sensors, this is merely illustrative. The same features may be applied to pixels in frontside illuminated image sensor pixels, if desired.

In accordance with various embodiments, an image sensor pixel may be configured to generate charge in response to incident light and may include a semiconductor layer having opposing first and second surfaces, the incident light passing through the first surface. The image sensor pixel may include an etched microlens on the first surface of the semiconductor layer and an interlayer dielectric on the second surface of the semiconductor layer, and the etched microlens and semiconductor layer may have at least one silicon—silicon-oxide interface.

In accordance with an embodiment, the at least one silicon—silicon-oxide interface may be configured to promote absorption of high-wavelength light within the semiconductor layer, and the interlayer dielectric may have trenches that extend toward the second surface.

In accordance with an embodiment, the etched microlens may comprise concentric ring-shaped portions that are configured to direct the light toward a central portion of the semiconductor layer.

In accordance with an embodiment, the concentric ring-shaped portions may be trenches in the first surface.

In accordance with an embodiment, the trenches may include first trenches and second trenches, the first trenches may be closer to the central portion of the semiconductor layer than the second trenches, and the first trenches may be shallower than the second trenches.

In accordance with an embodiment, the first trenches may have a higher refractive index than the second trenches.

In accordance with an embodiment, etched microlens may comprise concentric square-shaped portions that are configured to direct the light toward a central portion of the semiconductor layer.

In accordance with an embodiment, the etched microlens may comprise concentric ring-shaped portions and additional edge portions, and the ring-shaped portions and the additional edge portions may be configured to direct the light toward a central portion of the semiconductor layer.

In accordance with an embodiment, the interlayer dielectric may be formed from a dielectric material selected from the group consisting of: silicon nitride and silicon oxide. In accordance with an embodiment, a combined height of the semiconductor layer, the etched microlens, and the interlayer dielectric may be less than 5 microns.

In accordance with an embodiment, the image sensor pixel may further include an optical stack formed over the etched microlens, and the optical stack may include one or more of a color filter, a planarization layer, and an antireflection layer.

In accordance with various embodiments, an infrared-light sensitive image sensor pixel may include a silicon layer having opposing first and second surfaces, an infrared-light-absorption-promotion structure on the first surface, and a dielectric layer on the second surface having trenches that extend toward the second surface of the silicon layer.

In accordance with an embodiment, the infrared-light-absorption-promotion structure may be an etched microlens.

In accordance with an embodiment, the etched microlens and the silicon layer have at least one silicon—silicon-oxide interface that enhances infrared light absorption.

In accordance with an embodiment, the infrared-light-absorption-promotion structure may be a conductive patch, and the infrared-light sensitive image sensor pixel may further include a microlens that focuses incident light on the silicon layer. The conductive patch may be interposed between the microlens and the silicon layer.

In accordance with an embodiment, the conductive patch may be formed from a conductive material selected from the group consisting of: tungsten, WSi, nickel, and NiSi.

In accordance with an embodiment, a silicon-oxide interfacial layer may be interposed between the silicon layer and the conductive patch.

In accordance with an embodiment, the microlens may be formed from a material selected from the group consisting of: acrylic, glass, and polymer.

In accordant with various embodiments, an image sensor pixel may include a silicon layer having a first surface and an opposing second surface, an etched microlens on the first surface, and a dielectric layer on the second surface. The etched microlens may have a first plurality of trenches that extend into the first surface, the etched microlens may be configured to increase the absorption of infrared light by the silicon layer, and the dielectric layer may have a second plurality of trenches that extend into the second surface.

In accordance with an embodiment, the etched microlens and silicon layer may have a selected one of silicon—silicon-oxide interfaces and silicon—silicon-nitride interfaces.

The foregoing is merely illustrative and various modifications can be made to the described embodiments. The foregoing embodiments may be implemented individually or in any combination.

What is claimed is:

1. An image sensor pixel configured to generate charge in response to incident light, the image sensor pixel comprising:
a semiconductor layer having opposing first and second surfaces, wherein the incident light passes through the first surface;
an etched microlens on the first surface of the semiconductor layer, wherein the etched microlens and semiconductor layer have at least one silicon—silicon-oxide interface; and
an interlayer dielectric on the second surface of the semiconductor layer.

2. The image sensor pixel defined in claim 1 wherein the at least one silicon—silicon-oxide interface is configured to promote absorption of high-wavelength light within the semiconductor layer and wherein the interlayer dielectric has trenches that extend toward the second surface.

3. The image sensor pixel defined in claim 2 wherein the etched microlens comprises concentric ring-shaped portions that are configured to direct the light toward a central portion of the semiconductor layer.

4. The image sensor pixel defined in claim 3 wherein the concentric ring-shaped portions are trenches in the first surface.

5. The image sensor pixel defined in claim 4 wherein the trenches comprise first trenches and second trenches, wherein the first trenches are closer to the central portion of the semiconductor layer than the second trenches, and wherein the first trenches are shallower than the second trenches.

6. The image sensor pixel defined in claim 5 wherein the first trenches have a higher refractive index than the second trenches.

7. The image sensor pixel defined in claim 2 wherein the etched microlens comprises concentric square-shaped portions that are configured to direct the light toward a central portion of the semiconductor layer.

8. The image sensor pixel defined in claim 2 wherein the etched microlens comprises concentric ring-shaped portions and additional edge portions, and wherein the ring-shaped portions and the additional edge portions are configured to direct the light toward a central portion of the semiconductor layer.

9. The image sensor pixel defined in claim 1 wherein the interlayer dielectric is formed from a dielectric material selected from the group consisting of: silicon nitride and silicon oxide.

10. The image sensor pixel defined in claim 1 wherein a combined height of the semiconductor layer, the etched microlens, and the interlayer dielectric is less than 5 microns.

11. The image sensor pixel defined in claim 1 further comprising an optical stack formed over the etched microlens, wherein the optical stack includes one or more of a color filter, a planarization layer, and an antireflection layer.

12. An infrared-light sensitive image sensor pixel comprising:
a silicon layer having opposing first and second surfaces;
an infrared-light-absorption-promotion structure on the first surface; and
a dielectric layer on the second surface having trenches that extend toward the second surface of the silicon layer.

13. The infrared-light sensitive image sensor pixel defined in claim 12 wherein the infrared-light-absorption-promotion structure is an etched microlens.

14. The infrared-light sensitive image sensor pixel defined in claim 13 wherein the etched microlens and the silicon layer have at least one silicon—silicon-oxide interface that enhances infrared light absorption.

15. The infrared-light sensitive image sensor pixel defined in claim 12 wherein the infrared-light-absorption-promotion structure is a conductive patch, the infrared-light sensitive image sensor pixel further comprising:
a microlens that focuses incident light on the silicon layer, wherein the conductive patch is interposed between the microlens and the silicon layer.

16. The infrared-light sensitive image sensor pixel defined in claim 15 wherein the conductive patch is formed from a conductive material selected from the group consisting of: tungsten, WSi, nickel, and NiSi.

17. The infrared light-sensitive image sensor pixel defined in claim 16 further comprising a silicon-oxide interfacial layer interposed between the silicon layer and the conductive patch.

18. The infrared light-sensitive image sensor pixel defined in claim 15 wherein the microlens is formed from a material selected from the group consisting of: acrylic, glass, and polymer.

19. An image sensor pixel comprising:
a silicon layer having a first surface and an opposing second surface;
an etched microlens on the first surface, wherein the etched microlens has a first plurality of trenches that extend into the first surface, and wherein the etched microlens is configured to increase the absorption of infrared light by the silicon layer; and
a dielectric layer on the second surface, wherein the dielectric layer has a second plurality of trenches that extend into the second surface.

20. The image sensor pixel defined in claim 19 wherein the etched microlens and silicon layer have a selected one of silicon—silicon-oxide interfaces and silicon—silicon-nitride interfaces.
